(19) United States
(12) Patent Application Publication
(10) Pub. No.: US 2005/0227500 A1
(43) Pub. Date: Oct. 13, 2005

(54) Method for producing material of electronic device

(75) Inventors: Takuya Sugawara, Yamanashi (JP); Yoshihide Tada, Yamanashi (JP); Tomohiro Ohta, Yamanashi (JP)

Correspondence Address: CROWELL & MORING LLP;INTELLECTUAL PROPERTY GROUP, P.O. BOX 14300, WASHINGTON, DC, 20044-4300, US

(73) Assignee: TOKYO ELECTRON LIMITED, Tokyo (JP)

(21) Appl. No.: 10/509,372

(22) PCT Filed: Mar. 31, 2003
(86) PCT No.: PCT/JP03/04128

§ 371 Date: Sep. 28, 2004

(30) Foreign Application Priority Data
Mar. 29, 2002 (JP) 2002-97921

(51) Int. Cl. H01L 21/336

(52) U.S. Cl. 438/785; 438/287; 438/788

(57) ABSTRACT

A film is formed on the surface of an electronic device substrate by using plasma based on microwave irradiation via a plane antenna member having a plurality of slits in the presence of a process gas comprising at least a gas containing a film-forming substance and a rare gas. An insulating film capable of forming an electronic device substrate with an insulating film having a good electrical property can be formed.

### TECHNICAL FIELD

The present invention relates to a process for producing a material for electronic device, which is capable of producing an electronic device material containing an insulating film having a good electric property.

### BACKGROUND ART

In general, the present invention is widely applicable to the production of materials for electronic devices such as semiconductors or semiconductor devices, and liquid crystal devices. For the convenience of explanation, however, the background art relating to semiconductor devices as an example of the electronic devices, will be described here.

Substrates or base materials for semiconductors or electronic device materials such as silicon are subjected to various kinds of treatments such as formation of an insulating film such as oxide film, film formation by CVD (chemical vapor deposition), etc., and etching.

It is not too much to say that the development in the performances of semiconductor devices in recent years is attributable to the microfabrication technique concerning the semiconductor devices such transistor. At present, the microfabrication technique concerning the semiconductor devices is being improved for the purpose of attaining further development in the performances of semiconductor devices. According to the recent requirement for forming microstructures and attaining further development in the performances in the field of semiconductor devices, the demand for an insulating film having a higher performance (for example, in view of leakage current) has been increased remarkably. This is because the leakage current of a certain degree can have a stronger influence so as to cause a severe problem (e.g., in view of the electric power consumption) in the recent devices which have attained a finer structure, a higher degree of integration and/or higher performances, even when the leakage current of such a degree have actually caused substantially no problem in the conventional devices having a lower degree of integration. Particularly, in view of the development in the mobile or portable-type electronic devices in a so-called “ubiquitous” society of recent construction (i.e., information-oriented society wherein people can use a network service, anytime and anywhere, by means of electronic devices), the reduction in the leakage current is an extremely important issue.

Specific examples thereof will be described below. For example, with respect to the development of a next-generation MOS transistor, as the above-mentioned microfabrication technique is advanced, further film-thinning of a gate insulator is required. More specifically, in view of the processing technique, it is possible to reduce the film thickness of a silicon oxide (SiO₂) film which has been used as a gate insulator, to the utmost limit thereof (i.e., a level corresponding to one or two atom-layer). However, when the film thickness is reduced to 2 nm or less, an exponential increase in the leakage current is caused by the direct tunneling due to quantum effect, whereby the resultant power consumption is problematically increased.

At present, the IT (information technology) market is going to be transformed from the stationary-type electronic devices represented by desktop-type personal computers or home telephones (i.e., devices supplied with electricity from a plug socket) into “ubiquitous network society” wherein people can access the Internet, etc., anywhere and anytime. Accordingly, it is considered that mobile terminals such as cellular phone or car navigation system will become predominant in the near future. Such mobile terminals, per se are required to be high-performance devices. In addition, they should satisfy a prerequisite that they are small-sized, light in weight, and have a function capable of being used for a long time, although these performances are not necessarily required for the stationary-type devices. Accordingly, in the field of a mobile terminal, it is an extremely important issue to accomplish the reduction in power consumption and to accomplish the above-mentioned high performances simultaneously.

As described above, for example, with respect to the development of the above-mentioned next-generation MOS transistor, when the microfabrication of a high-performance silicon LSI is investigated, there occurs a problem that the leakage current is increased and the resultant power consumption is also increased. Accordingly, in order to accomplish a higher performance while reducing the power consumption, it is necessary that the performance of an MOS transistor is enhanced without increasing the gate leakage current therein.

In order to meet this demand for the realization of a high-performance and low-power consumption transistor, various techniques (for example, the reforming of silicon oxide film or use of silicon oxynitride film SiON) have been proposed. Another useful technique for attaining the above transistor is the development of a gate insulating film using a high-dielectric constant (high-K) material, that is, a material having a dielectric constant higher than that of SiO₂ film. When such a high-dielectric constant material is used, the EOT (equivalent oxide thickness), which is an SiO₂-equivalent physical film thickness can be (physically) increased so that a large reduction of the power consumption can be expected.

As the method of forming a film comprising a high-dielectric constant material, studies are being made, for example, on PVD (physical vapor deposition) such as electron beam vapor deposition and sputtering, and on thermal CVD utilizing thermal reaction, etc. However, the PVD method is vastly inferior to the CVD method in view of the uniformity or film quality, and therefore, the practical utility thereof is relatively little.

On the other hand, in the thermal CVD method, the film is generally formed by using a film-forming gas containing an organic source (for example, an organometallic compound such as Ta(OC₂H₅)₅ and Zr(OC₄H₉)₄) and thermal reacting the gas. Therefore, a problem attributable to the presence of an organic material (carbon) in the film is liable to be caused. That is, when carbon is present in the film, this may disadvantageously cause great deterioration in the film quality. Accordingly, in order to remove the carbon, it is usually required to form the film at a high temperature (see, C. Chaneliere, J. L. Autran, R. A. B. Devine and B. Ballade, Material Science Engineering, R.22, 269 (1998); M. A. Cameron and S. M. Geroge, Thin Solid Films, 348, 90-98 (1999); Satoshi Kamiyama, “DRAM yo Ta₂O₅ Capacitor Keisei Gijutsu (Technique for Forming Ta₂O₅ Capacitor for DRAM)”, Oyo Butsuri (Applied Physics), Vol. 69, No. 9, pp. 1067-1073 (2000); Yuzuru Oji et al., “DRAM Capacitor e no Koyudentai Hakumaku no Oyo—Kadai to Hoko (Application of High Dielectric Thin Film to DRAM Capacitor—Problem and Direction—”, Oyo Butsuri (Applied Physics), Vol. 66, No. 11, pp. 1210-1214 (1997); and Kaupo KuKli, Mikko Ritala and Markku Leskela, J. Electrochemical Society, Vol. 142, No. 5, pp. 1670-1675 (May, 1995)).

In the film formation at a high temperature, carbon is combusted by the reaction thereof with oxygen contained in the surrounding atmosphere, and the carbon concentration in the film is considered to be decreased. However, the reaction rate in the treatment at a high temperature is determined by the supply rate-limiting, and therefore, there is a strong tendency to make it difficult to form a uniform film.

Further, the high-dielectric constant materials generally have a low heat stability and can be crystallized at a high temperature so as to form grain boundaries, to thereby cause a problem such as deterioration of device properties. If the treatment is performed at a low temperature so as to obtain the uniformity and to prevent the crystallization, there is liable to occur a problem such that a large amount of carbon remains in the film, to the contrary, or a large number of weak bonds (for example, in the case of silicate, weak Si—Si bonds) are contained in the film.

In order to overcome these defects, there has been proposed the film formation of a high-K material by using plasma CVD (see, Byeong-ok Cho, Sandy Lao, Lin Sha and Jane P. Chang, Journal of Vacuum Science and Technology, A19(6), pp. 2751-2761 (November/December 2001); Benjamin Chin-ming Lai, Nan-hui Kung and Ya-min Lee, Journal of Applied Physics, Vol. 85, No. 8, pp. 4087-4090 (Apr. 15, 1999); Hiromitsu Kato, Tomohiro Nango, Takeshi Miyagawa, Takahiro Katagiri, Yoshimitsu Ohki, Kwang Soo Seol and Makoto Takyama, 2001 Dry Process International Symposium Proceeding, pp. 175-180; Gerald Lucovsky, Hiro Niimi, Robert Jhonson, Joon Goo Hong, Robert Therrien and Bruce Rayner, SSDM 2000, Abstracts, pp. 232-233). In the plasma process, the film can be formed at a substrate temperature up to about 400° C., and in this temperature region, a large amount of reactive oxygen species can be produced, so that a high-dielectric constant material having a low carbon concentration can be produced at a low temperature (see, the above-mentioned paper by Byeong-Ok Cho et al.)

However, when a high-dielectric constant material layer is formed by the conventional plasma CVD film-forming technique, the resultant film is not always an insulating film having a good electrical property. According to the knowledge and investigation of the present inventors, it is presumed that this phenomenon is attributable to a fact that the properties such as plasma density and electron temperature employed for the plasma film formation technique in the prior art are not satisfactory at the time of the application thereof to the above-mentioned process.

### DISCLOSURE OF INVENTION

An object of the present invention is to provide a process for producing an electronic device material which can solve the problem encountered in the prior art.

A specific object of the present invention is to provide a process for producing an electronic device material having a good electrical property.

As a result of earnest study, the present inventors have found that it is extremely effective in achieving the above-mentioned object, to form a film by using a specific plasma-based CVD treatment, rather than a plasma which has been used in the prior art.

The process for producing an electronic device material according to the present invention is based on this discovery. More specifically, this process comprises: forming a film on the surface of an electronic device substrate by using a plasma based on microwave irradiation via a plane antenna member having a plurality of slits, in the presence of a process gas comprising at least a gas containing a film-forming substance and a rare gas.

In the process for producing an electronic device material according to the present invention having the above constitution, the microwave irradiation is effected via a plane antenna member so as to generate plasma having a high density and a low electron temperature over a wide range, while maintaining a high uniformity thereof, whereby a film having a good electrical property can be obtained.

According to the present inventors' knowledge and investigations, the reason for the formation of such a film having a good electrical property in the present invention is presumed in the following manner.

That is, in the present invention, when plasma having a high density and a low electron temperature is generated over a wide range, while maintaining a high uniformity, by using microwave irradiation via a plane antenna member, a high oxygen radical density is provided to thereby combust the carbon content in the film-forming reactive species, simultaneously with the film formation. When this method is used, the combustion of the carbon content can be accelerated than that in the case of the combustion of the carbon content wherein oxygen radicals are supplied to the film after the film formation. It is presumed that a film having a good electrical property is obtained because of such a reduction of the carbon content.

On the other hand, according to the present inventors' knowledge and investigations, the parallel plate-type RF plasma, the induction coil-type (ICP) plasma and the ECR plasma, which are currently employed, are found to have the following problems in the plasma characteristic.

The parallel plate-type RF plasma generally has an electron density of 1E9 to 1E11/cm³ and an electron temperature of 3 to 4 eV. This is plasma having a low electron density and a high electron temperature and a sufficiently large amount of reactive species may not be formed due to the low density, or the high electron temperature may cause electric charge bombardment in the film or plasma damage to the substrate. Further, the ICP plasma has a sufficiently high density of 1E10 to 1E12/cm³, but the electron temperature thereof is as high as 3 to 4 eV and this inevitably causes damage to the film to be formed or the substrate.

Further, in the ECR plasma, the electron density can be controlled over a wide range from 1E9 to 1E13/cm³, but the electron temperature thereof is as high as 2 to 7 eV, and since the electron density and the electron temperature are in a trade-off relationship, plasma having both of a high density and a low electron temperature can be hardly formed (as described in the above-mentioned publication by Byeong-Ok Cho et al.). Accordingly, it is difficult to achieve the “reduction of carbon content” as in the present invention.

Further, the conventional parallel plate-type RF plasma and ECR plasma both have a common problem that they can hardly be applied to a large-area process. Therefore, it is extremely difficult to apply these methods to a 300-mm wafer process, although such a large-area process is expected to make a great progress in the near future in view of mass production.

On the other hand, the plane antenna for use in the present invention is characterized in that it can easily be applied to a large-area process because of a surface wave plasma to be provide thereby, and therefore the plane antenna can easily be applied to a 300-mm wafer process which is expected to make a great progress in the near future in view of mass production.

### BRIEF DESCRIPTION OF DRAWINGS

FIG. 1 is a schematic vertical sectional view showing an example of the semiconductor device which can be produced by the process for producing an electronic device material according to the present invention.

FIG. 2 is a schematic plan view showing an example of the semiconductor manufacturing equipment for conducting a process for producing electronic device material according to the present invention.

FIG. 3 is a schematic vertical sectional view showing an example of the plasma processing unit comprising a slit plane (or planar) antenna (RLSA, sometimes also referred to as “Slot Plane Antenna” or “SPA”), which is usable in the process for producing electronic device material according to the present invention.

FIG. 4 is a schematic plan view showing an example of the RLSA which is usable in the apparatus for modifying an insulating film according to the present invention.

FIG. 5 is a schematic vertical sectional view showing an example of the heating reaction furnace unit which is usable for the process for producing electronic device material according to the present invention.

FIG. 6 is a flow chart showing examples of the respective steps in the production process according to the present invention.

FIG. 7 is a schematic sectional view showing an example of the film formation by the production process according to the present invention.

FIG. 8 is a graph showing a profile by Auger electron spectroscopy of ZrO₂ produced by an ordinary thermal CVD.

FIG. 9 shows a relationship between the ratio of emission intensity of plasma and the carbon concentration in a film determined by an XPS analysis.

FIG. 10 is a graph showing the electron temperature of an ECR plasma used in FIG. 9.

FIG. 11 is a graph showing the horizontal direction analysis of the electron temperature of plasma when microwave irradiation is effected via a plane antenna member.

FIG. 12 is a graph showing the horizontal direction analysis of the electron temperature of plasma when microwave irradiation is effected via a plane antenna member.

### BEST MODE FOR CARRYING OUT THE INVENTION

Hereinbelow, the present invention will be described in detail with reference to the accompanying drawings as desired. In the following description, “%” and “part(s)” representing a quantitative proportion or ratio are those based on mass, unless otherwise specifically noted.

(Process for Producing Electronic Device Material)

In the present invention, a film is formed on the surface of an electronic device substrate by using a plasma based on microwave irradiation via a plane antenna member having a plurality of slits, in the presence of a process gas comprising at least an oxygen atom-containing gas and a rare gas.

(Electronic Device Substrate)

The electronic device substrate which can be used in the present invention is not particularly limited, but may be a substrate (or base material) which is appropriately selected from any one of known electronic device substrates, or a combination of two or more kinds thereof. Specific Examples of the electronic device substrate may include: semiconductor materials and liquid crystal device materials. Examples of the semiconductor material may include materials mainly comprising a single-crystal silicone, and examples of the liquid crystal device material may include a glass substrate.

(Process Gas)

The process gas for use in the present invention comprises at least a film forming substance-containing gas, and a rare gas. The process gas may also contain, as desired, another gas described later, in addition to the film forming substance-containing gas, and rare gas.

(Film Forming Substance)

The film forming substance which can be used in the present invention is not particularly limited, as long as it is a substance capable of providing a film or layer on the above-mentioned electronic device substrate on the basis of a vapor deposition process. In view of recent requirements (e.g., finer structure, larger-area film process, lower-temperature treatment) on the market, for example, a film-forming substance for gate insulator and/or a film-forming substance for interlayer insulating film can particularly suitably e used as the film-forming substance.

(Film-Forming Substance for Gate insulator)

The film-forming substance for gate insulator, which can be used in the present invention, is not particularly limited as long as it is a substance capable of providing an insulating film or layer on the electronic device substrate based on the vapor deposition process. In view of easily provision of the above-mentioned suitable EOT, this film-forming substance for gate insulator may preferably be a high-dielectric constant (high-K) material, that is, a substance having a dielectric constant of 7.0 or more.

Examples of the film-forming substance for gate insulator, which can suitably be used in the present invention, may include one or more substance selected from SiO₂, Si₃N₄, Ta₂O₅, ZrO₂, HfO₂, Al₂O₃, La₂O₃, TiO₂, Y₂O₃, BST (barium.strontium titanate (Ba,Sr)TiO₃), Pr₂O₃, Gd₂O₃, CeO₂ and compounds of these substances.

(Film-Forming Substance for Interlayer Insulating Film)

The film-forming substance for interlayer insulating film, which can be used in the present invention, is not particularly limited, as long as it is a substance capable of providing an interlayer insulating film or layer on the electronic device substrate on the basis of a vapor deposition process. The interlayer insulating film may generally be a thick film (1,000 A (angstrom) or more), and therefore, it is necessary to use a film formation process having a high film formation rate and a low plasma damage. In this meaning, the plasma having a high density and a low electron temperature according to the present invention can suitably be used. Further, the interlayer insulating film should decrease the resistance-capacitance (RC) delay therein, and a low dielectric constant (low-k) film should generally be used therefor. For the purpose of achieving a suitable low dielectric constant, the film-forming substance for the interlayer insulating film may preferably contain one or at least two atoms selected from the group consisting of Si, C, O, F, N and H.

Examples of the film-forming substance for the interlayer insulating film, which can suitably be used in the present invention, may include at least one substance selected from SiO₂, SiO₃F₂, MSQ, HSQ, Teflon (polytetrafluoroethylene), a-C:F and compounds of these substances.

(Organic Source)

The organic source (organometallic compound) which can be used in the present invention is not particularly limited, as long as it is a substance capable of providing a gate insulator or layer on the above-mentioned electronic device substrate based on the vapor deposition process.

Examples of the organic source which can suitably be used in the present invention may include Ta(OC₂H₅)₅, Zr(OC₄H₉)₄ and Hf(OC₄H₉)₄.

(Process Gas Conditions)

In the insulating film formation according to the present invention, the following conditions may preferably be used, in view of the characteristic of the insulating film to be formed.
Rare Gas (e.g., Kr, Ar, He, or Xe): from 500 to 3,000 sccm, more preferably from 1,000 to 2,000 sccm
O₂: from 10 to 500 sccm, more preferably from 40 to 200 sccm
Temperature: from room temperature (25° C.) to 600° C., more preferably from 250 to 500° C.
Pressure: from 3.3 to 267 Pa, more preferably from 6.7 to 133 Pa
Microwave: from 0.7 to 4.2 W/cm², more preferably from 1.4 to 4.2 W/cm², particularly preferably from 1.4 to 2.8 W/cm²
   (Preferred Plasma)

The plasma which can be preferably used in the present invention may be one having the following properties:
Electron Temperature: 3 eV or less, more preferably 2 eV or less
Electron Density: 1E10/cm³ or more, more preferably 1E11/cm³ or more
Uniformity of Plasma Density: within ±10%.
   (Plane Antenna Member)

In the production process for electronic device material according to the present invention, a plasma having a low electron temperature, a high density, and a high uniformity is formed by irradiating microwave via a plane antenna member having a plurality of slots. In the present invention, the film is formed by using the plasma having such an excellent characteristic, and therefore the present invention can provide a process which accomplishes a light plasma damage, and a high reactivity at a low temperature. Further, in the present invention, as compared with a case using conventional plasma, a high-quality insulating film may easily be formed by irradiating microwave via a plane antenna member.

According to the present invention, a high-quality film (for example, insulating film) can be formed. Accordingly, a semiconductor device structure having an excellent characteristic may easily be formed by forming another layer (for example, an electrode layer) on this insulating film.

(Preferred Characteristic of Insulating Film)

According to the present invention, an insulating film having the following preferred characteristic can easily be formed.

Carbon content in Film (measured by SIMS analysis): preferably 20% or less, more preferably 15% or less

(Preferred Characteristic of Semiconductor Structure)

The extent to which the process according to the present invention is applied is not particularly limited, but the high-quality insulating film formable by the present invention can suitably be used, particularly as a gate insulator constituting an MOS structure.

(Preferred Characteristic of MOS Semiconductor Structure)

The very thin insulating film having a good quality, which can be formed by the present invention, can suitably be used particularly as an insulating film constituting a semiconductor device (particularly, as a gate insulator constituting an MOS semiconductor structure).

According to the present invention, an MOS semiconductor structure having the following preferred characteristic can easily be produced. When the characteristic of the insulating film which has been modified by the present invention is evaluated, for example, a standard MOS semiconductor structure as described in a publication (see, Masanori Kishino and Mitsumasa Koyanagi, “VLSI Device no Butsuri (Physics of VLSI Device)”, pp. 62-63, published by Maruzen) is fabricated and the evaluation of the characteristic of the thus fabricated MOS can be used as the evaluation of the characteristic of the insulating film itself. This is because, in such a standard MOS structure, the characteristic of the insulating film constituting the MOS structure has much effect on the MOS characteristic.

(One Embodiment of Production Apparatus)

One preferred embodiment of the production process according to the present invention is described below.

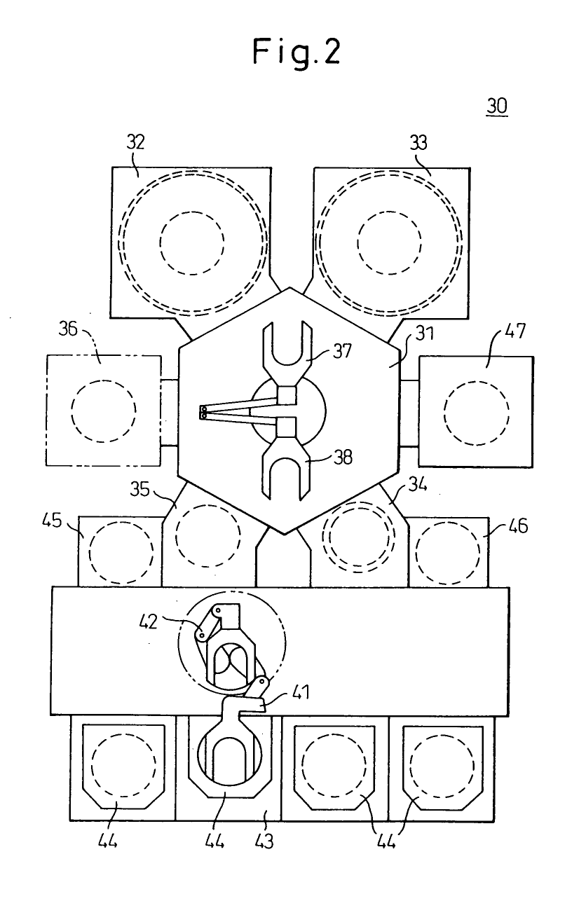

First, as an example of the structure of a semiconductor device which can be produced by the process for producing an electronic device material according to the present invention, a semiconductor device having an MOS structure having a gate insulator as the insulating film is described below with reference to FIG. 2.

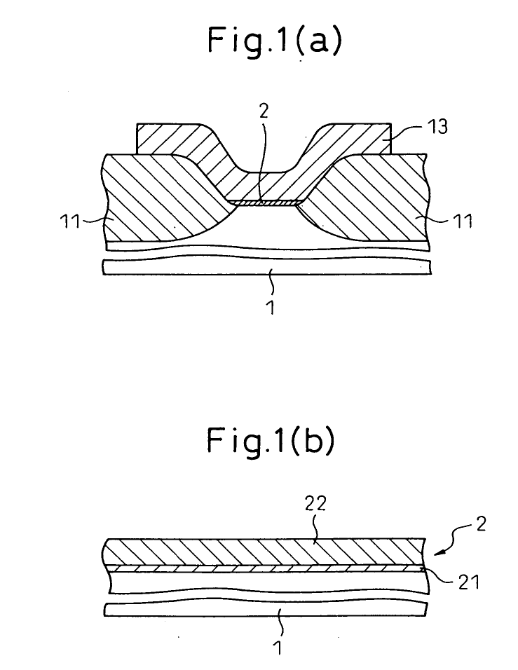

Referring to FIG. 1(a), the reference numeral 1 in this FIG. 1(a) denotes a silicon substrate, numeral 11 denotes a field oxide film, numeral 2 denotes a gate insulator and numeral 13 denotes a gate electrode. As described above, the production process according to the present invention may provide a very thin gate insulator 2 having a good quality. As shown in FIG. 1(b), this gate insulator 2 sometimes comprises a stacked or laminate structure together with a high-quality insulating film formed at the interface with the silicon substrate 1. The gate insulator may sometimes be constituted by an oxide film 21 having a thickness of 1.0 nm, for example, and an insulating film 22 formed on the upper part thereof.

In this example, it is preferred that the high-quality oxide film 21 comprises a silicone oxide film (hereinafter referred to as “SiO₂ film”) which has been formed by irradiating a substrate to be treated mainly comprising Si, with a microwave through a plane antenna member having a plurality of slots in the presence of a process gas comprising O₂ and a rare gas so as to generate plasma, and forming the oxide film on the surface of the substrate by using the thus generated plasma. When such SiO₂ is used, the structure of the apparatus to be used therefor is the same as that of the apparatus for forming an insulating film. As a result, it is possible to obtain an advantage that the film can be formed in the same chamber, or operationality can be improved, or the space for the apparatus (foot-print) can be saved, because of the same specification between these apparatuses.

In the present invention, in view of the reduction effect in the electrical film thickness, the surface of the silicon oxide film 21 may preferably be subjected to a nitridation treatment by introducing a nitrogen gas into the above-mentioned plasma. Alternatively, instead of the silicon oxide film 21, it is also possible to use a plasma nitride film which has been formed by introducing a nitrogen gas directly into the plasma on the Si substrate. On the silicon oxide film, oxynitride film or nitride film, a gate insulator 22 is formed by using the process according to present invention, and further, a gate insulator 13 mainly comprising silicon (polysilicon or amorphous silicon) is formed. The gate insulator 22 according to the present invention may also be formed directly on the Si substrate.

(One Embodiment of Production process)

Next, the process for producing such an electronic device material where a gate insulator 2 is provided and a gate electrode 13 is further provided thereon is described below.

FIG. 2 is schematic view (schematic plan view) showing an example of the total arrangement of a semiconductor manufacturing equipment 30 for conducting the process for producing an electronic device material according to the present invention.

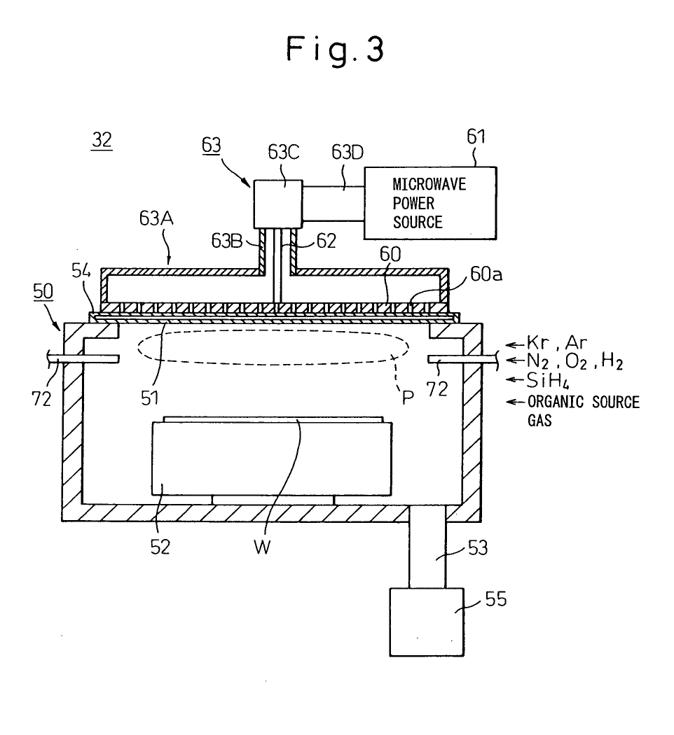

As shown in FIG. 2, in a substantially central portion of the semiconductor manufacturing equipment 30, there is disposed a transportation chamber 31 for transporting a wafer W (FIG. 3). Around the transportation chamber 31, there are disposed: plasma processing units 32 and 33 for conducting various treatments on the wafer, two load lock units 34 and 35 for conducting the communication/cutoff between the respective processing chambers, a heating unit 36 for operating various heating treatments, and a heating reaction furnace 47 for conducting various heating treatments on the wafer. These units are disposed so as to surround the transportation chamber 31. Alternatively, it is also possible to provide the heating reaction furnace 47 independently and separately from the semiconductor manufacturing equipment 30.

On the side of the load lock units 34 and 35, a preliminary cooling unit 45 and a cooling unit 46 for conducting various kinds of preliminary cooling and cooling treatments are disposed.

In the inside of transportation chamber 31, transportation arms 37 and 38 are disposed, so as to transport the wafer W (FIG. 2) between the above-mentioned respective units 32-36.

On the foreground side of the load lock units 34 and 35 in this figure, loader arms 41 and 42 are disposed. These loader arms 41 and 42 can put wafer W in and out with respect to four cassettes 44 which are set on the cassette stage 43, which is disposed on the foreground side of the loader arms 41 and 42.

In FIG. 2, as the plasma processing units 32 and 33, two plasma processing units of the same type are disposed in parallel.

Further, it is possible to exchange both of the plasma processing units 32 and 33 with a single-chamber type CVD process unit. It is possible to set one or two of such a single-chamber type CVD process unit in the position of plasma processing units 32 and 33.

When two plasma processing units 32 and 33 are used, it is possible that an SiO₂ film is formed in the plasma processing unit 32, and a CVD film is formed in the plasma processing unit 33. Alternatively, it is also possible that the formation of an SiO₂ film and the formation of a CVD film are conducted in parallel, in the plasma processing units 32 and 33. Further, it is also possible that an SiO₂ film is formed in another apparatus, and the SiO₂ film is surface-nitrided in parallel, in the plasma processing units 32 and 33.

(One Embodiment of Film Formation of Gate Insulator)

FIG. 3 is a schematic sectional view in the vertical direction showing plasma processing unit 32 (or 33) which is usable in the film formation of the gate insulator 2.

Referring to FIG. 3, reference numeral 50 denotes a vacuum container made of, e.g., aluminum. In the upper portion of the vacuum container 50, an opening portion 51 is formed so that the opening portion 51 is larger than a substrate (for example, wafer W). A top plate 54 in a flat cylindrical shape made of a dielectric such as quartz or aluminum oxide so as to cover the opening portion 51. In the side wall of the upper portion of vacuum container 50 which is below the top plate 54, gas feed pipes 72 are disposed in the 16 positions, which are arranged along the circumferential direction so as to provide even intervals therebetween. A process gas comprising at least one kind of gas selected from O₂, rare gas, N₂, H₂, etc., can be supplied into the vicinity of the plasma region P in the vacuum container 50 from the gas feed pipes 72 evenly and uniformly.

On the outside of the top plate 54, there is provided a high-frequency power source, via a plane antenna member 60 having a plurality of slots, which comprises a plane antenna (RLSA) made from a copper plate, for example. As the high-frequency power source, a waveguide 63 is disposed on the top plate 54, and the waveguide 63 is connected to a microwave power supply 61 for generating microwave of 2.45 GHz, for example. The waveguide 63 comprises a combination of: a flat circular waveguide 63A, of which lower end is connected to the RLSA 60; a circular waveguide 63B, one end of which is connected to the upper surface side of the circular waveguide 63A; a coaxial waveguide converter 63C connected to the upper surface side of the circular waveguide 63B; and a rectangular waveguide 63D, one end of which is connected to the side surface of the coaxial waveguide converter 63C so as to provide a right angle therebetween, and the other end of which is connected to the microwave power supply 61.

In the present invention, a frequency region including UHF and microwave is referred to as high-frequency region. The high-frequency power supplied from the high-frequency power source may preferably have a frequency of not smaller than 300 MHz and not larger than 250 GHz, which may include UHF having a frequency of not smaller than 300 MHz and microwave having a frequency of not smaller than 1 GHz. In the present invention, the plasma generated by the high-frequency power is referred to as “high-frequency plasma”.

In the inside of the above-mentioned circular waveguide 63B, an axial portion 62 of an electroconductive material is coaxially provided, so that one end of the axial portion 62 is connected to the central (or nearly central) portion of the RLSA 60 upper surface, and the other end of the axial portion 62 is connected to the upper surface of the circular waveguide 63B, whereby the circular waveguide 63B constitutes a coaxial structure. As a result, the circular waveguide 63B is constituted so as to function as a coaxial waveguide.

In addition, in the vacuum container 50, a stage 52 for mounting the wafer W is provided so that the stage 52 is disposed opposite to the top plate 54. The stage 52 contains a temperature control member (not shown) disposed therein, so that the stage can function as a hot plate. Further, one end of an exhaust pipe 53 is connected to the bottom portion of the vacuum container 50, and the other end of the exhaust pipe 53 is connected to a vacuum pump 55.

(One Embodiment of RLSA)

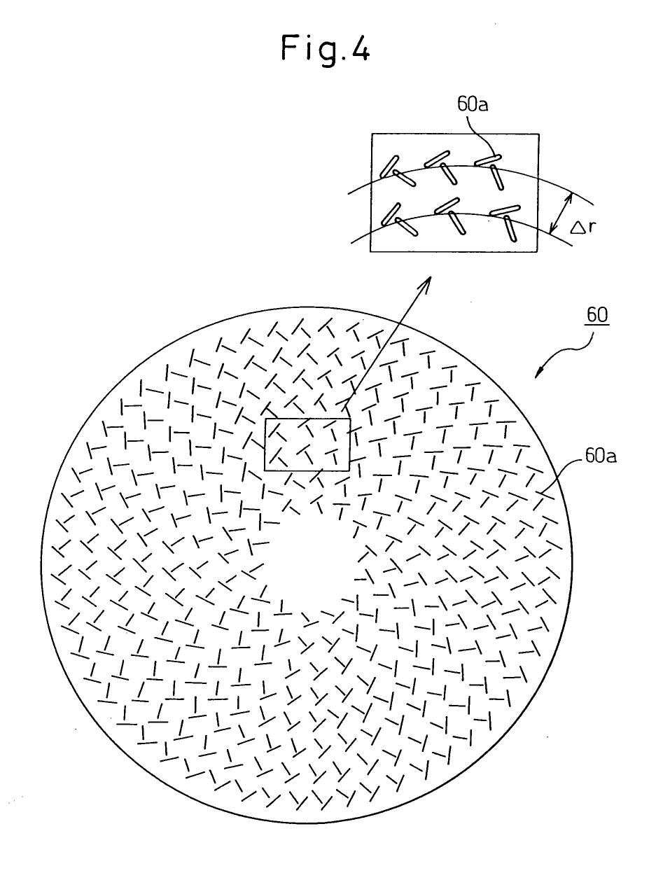

FIG. 4 is a schematic plan view showing an example of RLSA 60 which is usable in an apparatus for producing an electronic device material according to the present invention.

As shown in this FIG. 4, on the surface of the RLSA 60, a plurality of slots 60a, 60a, . . . . are provided in the form of concentric circles. Each slot 60a is a substantially square penetration-type groove. The adjacent slots are disposed perpendicularly to each other and arranged so as to form a shape of alphabetical “T”-type character. The length and the interval of the slot 60a arrangement are determined in accordance with the wavelength of the microwave supplied from the microwave power supply unit 61.

(One Embodiment of Heating Reaction Furnace)

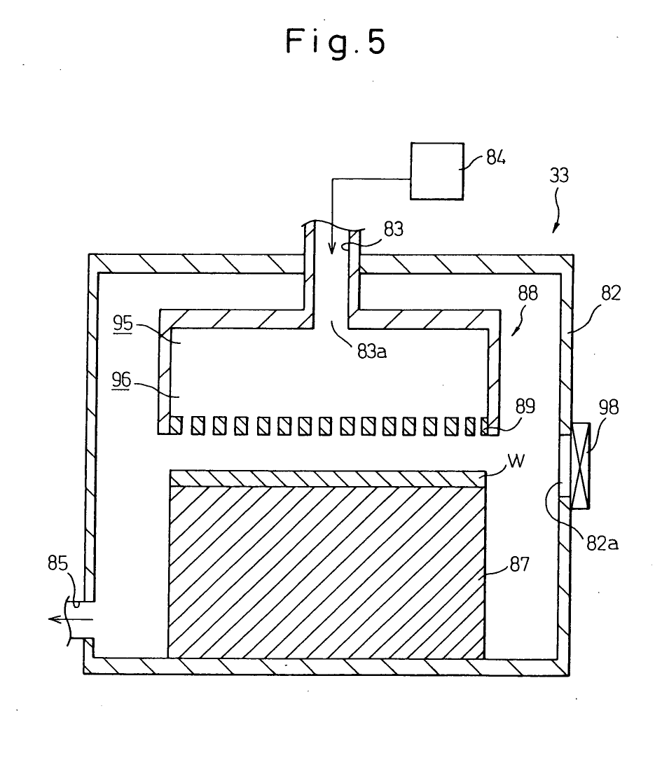

FIG. 5 is schematic sectional view in the vertical direction showing an example of the heating reaction furnace 47 which is usable in an apparatus for producing an electronic device material according to the present invention.

As shown in FIG. 5, a processing chamber 82 of the heating reaction furnace 47 chamber is formed into an air-tight structure by using aluminum, for example. A heating mechanism and a cooling mechanism are provided in the processing chamber 82, although these mechanisms are not shown in FIG. 5.

As shown in FIG. 5, a gas introduction pipe 83 for introducing a gas into the processing chamber 82 is connected to the upper central portion of the processing chamber 82, the inside of the processing chamber 82 communicates with the inside of the gas introduction pipe 83. In addition, the gas introduction pipe 83 is connected to a gas supply source 84. A gas is supplied from the gas supply source 84 into the gas introduction pipe 83, and the gas is introduced into the processing chamber 82 through the gas introduction pipe 83. As the gas in this case, it is possible to use one of various gas such as raw material for forming a gate electrode (electrode-forming gas) such as silane, for example. As desired, it is also possible to use a rare gas as a carrier gas.

A gas exhaust pipe 85 for exhausting the gas in the processing chamber 82 is connected to the lower portion of the processing chamber 82, and the gas exhaust pipe 85 is connected to exhaust means (not shown) such as vacuum pump. On the basis of the exhaust means, the gas in the processing chamber 82 is exhausted through the gas exhaust pipe 85, and the processing chamber 82 is maintained at a desired pressure.

In addition, a stage 87 for mounting wafer W is provided in the lower portion of the processing chamber 82.

In the embodiment as shown in FIG. 5, the wafer W is carried on the stage 87 by means of an electrostatic chuck (not shown) having a diameter which is substantially the same as that of the wafer W. The stage 87 contains a heat source means (not shown) disposed therein, to thereby constitute a structure wherein the surface of the wafer W to be processed which is carried on the stage 87 can be adjusted to a desired temperature.

The stage 87 has a mechanism which is capable of rotating the wafer W which carried the stage 87, as desired.

In FIG. 5, an opening portion 82a for putting the wafer W in and out with respect to the processing chamber 82 is provided on the surface of the right side of the processing chamber 82 in this figure. The opening portion 82a can be opened and closed by moving a gate valve 98 vertically (up and down direction) in this figure. In FIG. 5, a transportation arm (not shown) for transporting the wafer is provided adjacent to the right side of the gate valve 98. In FIG. 5, the wafer W can be carried on the stage 87, and the wafer W after the processing thereof is transported from the processing chamber 82, as the transportation arm enters the processing chamber 82 and goes out therefrom through the medium of the opening portion 82a.

Above the stage 87, a shower head 88 as a shower member is provided. The shower head 88 is constituted so as to define the space between the stage 87 and the gas introduction pipe 83, and the shower head 88 is formed from aluminum, for example.

The shower head 88 is formed so that the gas exit 83a of the gas introduction pipe 83 is positioned at the upper central portion of the shower head 88. The gas is introduced into the processing chamber 82 through gas feeding holes 89 provided in the lower portion of the shower head 88.

(Embodiment of the Insulating Film Formation)

Next, there is described a preferred embodiment of the process wherein an insulating film comprising a gate insulator 2 is formed on a wafer w by using the above-mentioned apparatus.

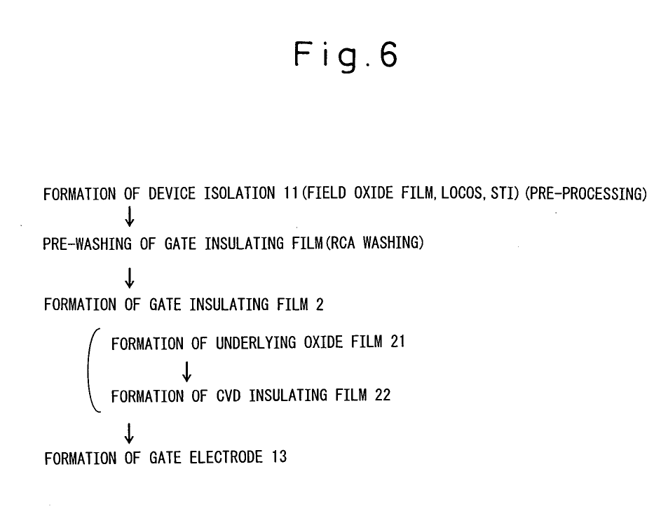

FIG. 6 is a flowchart showing an example of the flow of the respective steps constituting the production process according to the present invention.

Referring to FIG. 6, in a preceding step, a field oxide film 11 (FIG. 1(a)) is formed on the surface of a wafer W. Thereafter, a preliminary washing (RCA washing) is conducted, prior to the formation of a gate insulator.

Subsequently, a gate valve (not shown) provided at the side wall of the vacuum container 50 in the plasma processing unit 32 (FIG. 2) is opened, and the above-mentioned wafer W comprising the silicon substrate 1, and the field oxide film 11 formed on the surface of the silicon substrate 1 is placed on the stage 52 (FIG. 3) by means of transportation arms 37 and 38.

Next, the gate valve was closed so as to seal the inside of the vacuum container 50, and then the inner atmosphere therein is exhausted by the vacuum pump 55 through the exhaust pipe 53 so as to evacuate the vacuum container 50 to a predetermined degree of vacuum and a predetermined pressure in the container 50 is maintained. On the other hand, microwave (e.g., of 1.80 GHz and 2200 W) is generated by the microwave power supply 61, and the microwave passes through the waveguide so that the microwave is introduced into the vacuum container 50 via the RLSA 60 and the top plate 54, whereby high-frequency plasma is generated in the plasma region P of an upper portion in the vacuum container 50.

Herein, the microwave is transmitted in the rectangular waveguide 63D in a rectangular mode, and is converted from the rectangular mode into a circular mode by the coaxial waveguide converter 63C. The microwave is then transmitted in the cylindrical coaxial waveguide 63B in the circular mode, and transmitted in the circular waveguide 63A in the expanded state, and is emitted from the slots 60a of the RLSA 60, and penetrates the plate 54 and is introduced into the vacuum container 50. In this case, microwave is used, and accordingly a high-density and low-electron temperature plasma can be generated. Further, the microwave is emitted from a large number of slots 60a of the RLSA 60, and accordingly the plasma is caused to have a uniform distribution.

Subsequently, while the wafer W is heated to 400° C., for example, by regulating the temperature of the stage 52, the first step (formation of oxide film) is conducted by introducing via the gas feed pipe 72 a process gas for an oxide film formation comprising a rare gas such as krypton and argon, and O₂ gas at flow rates of 2000 sccm, and 200 sccm, respectively, at a pressure of 133 Pa.

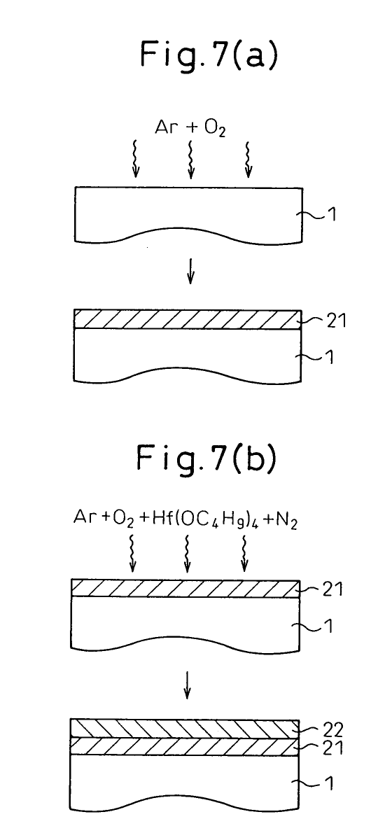

In this process, the introduced process gas is activated (so as to generate radicals) by plasma flux which has been generated in the plasma processing unit 32, and on the basis of the thus generated plasma, as shown in the schematic sectional view of FIG. 7A, the surface of the silicon substrate 1 is oxidized, to thereby form an oxide film (SiO₂ film) 21. In this manner, the oxidation step is conducted for 10 seconds, for example, so that a gate oxide film or underlying oxide film (underlying SiO₂ film) 21 having a thickness of 0.8 nm can be formed.

Next, the gate valve (not shown) is opened, and the transportation arms 37 and 38 (FIG. 2) are caused to enter the vacuum container 50, so as to receive the wafer W on the stage 52. The transportation arms 37 and 38 take out the wafer W from the plasma processing unit 32, and then set the wafer W in the stage in the adjacent plasma processing unit 33. Alternatively, depending on the application or usage of the wafer, it is also possible to transport the wafer to the heat reaction furnace 47 without conducting a treatment on the gate oxide film in the unit 33.

(Embodiment of Nitride-Containing Layer Formation)

Subsequently, the wafer W is subjected to a CVD treatment according to the present invention in the plasma processing unit 33, and a high-K insulating film 22 (FIG. 7B) is formed on a surface portion of the underlying oxide (underlying SiO₂) film 21 which has been formed in advance.

At the time of the high-K CVD film-forming treatment, for example, it is possible that argon gas, O₂ gas, Hf(OC₄Hg)₄ gas which has been vaporized by a vaporizer, and a carrier gas (i.e., N₂ gas or rare gas such as argon) for carrying the vaporized gas from the vaporizer to the vacuum container, are introduced into the container 50 from the gas introduction pipe at flow rates of 2000 sccm (argon gas), 200 sccm (O₂ gas), 10 sccm (Hf(OC₄Hg)₄ gas), and 1000 sccm (carrier gas), respectively, in a state where the wafer temperature is 400° C., for example, and the process pressure is 66.7 Pa (500 mTorr), for example, in the vacuum container 50.

On the other hand, microwave, e.g., of 2 W/cm² is generated from the microwave power supply 61, and the microwave is guided by the waveguide so that the microwave is introduced into the vacuum container 50 via the RLSA 60 and the top plate 54, whereby high-frequency plasma is generated in the plasma region P of an upper portion in the vacuum container 50.

(Formation of CVD Insulating Film 22)

In this process (formation of CVD insulating film 22), the introduced gas is converted into plasma, and Hf and O radicals are generated. These Hf and O radicals are reacted on the SiO₂ film disposed on the wafer W upper surface, to thereby form HfO₂ on the SiO₂ film surface in a relatively short period. In this way, as shown in FIG. 7B, a high-K insulating film 22 is formed on the surface of the underlying oxide film (underlying SiO₂ film) 21 on the wafer W.

It is possible that a gate insulator having a thickness of about 1.5 nm in terms of the equivalent film thickness by conducting this CVD treatment for 20 seconds, for example.

(Embodiment of Gate Electrode Formation)

Next, a gate electrode 13 (FIG. 1A) is formed on the insulating film which has been formed by providing a high-K CVD film on the SiO₂ film or underlying SiO₂ film on the wafer W. In order to form the gate electrode 13, the wafer W on which the gate oxide film or gate oxynitride film has been formed is taken out from each of the plasma processing unit 32 or 33, so as to once accommodate the wafer W in the transportation chamber 31 (FIG. 2) side, and then the wafer W is accommodated into the heating reaction furnace 47. In the heating reaction furnace 47, the wafer W is heated under a predetermined processing condition to thereby form a predetermined gate electrode 13 on the gate oxide film or gate oxynitride film.

At this time, it is possible to select the processing condition depending on the kind of the gate electrode 13 to be formed.

More specifically, when the gate electrode 13 comprising poly-silicon is intended to be formed, the step is conducted under conditions such that SiH₄ is used as the process gas (electrode-forming gas), the pressure is 20-33 Pa (150-250 mTorr), and the temperature is 570-630° C.

On the other hand, when the gate electrode 13 comprising amorphous-silicon is intended to be formed, the step is conducted under conditions such that SiH₄ is used as the process gas (electrode-forming gas), the pressure is 20-67 Pa (150-500 mTorr), and the temperature is 520-570° C.

Further, when the gate electrode 13 comprising SiGe is intended to be formed, the step is conducted under conditions such that a mixture gas of GeH₄/SiH₄=10/90-60/40% is used, the pressure is 20-60 Pa, and the temperature is 460-560° C.

(Quality of Oxide Film)

In the above-mentioned first step, at the time of forming the gate oxide film or the underlying oxide film for a high-K gate insulator, the wafer W comprising Si as a main component is irradiated with microwave in the presence of a process gas via a plane antenna member (RLSA) having a plurality of slots, so as to form plasma comprising oxygen (O₂) and a rare gas, to thereby form the oxide film on the surface of the above-mentioned substrate to be processed. As a result, the underlying oxide film can be formed by the same action principle as that for the CVD film formation, and therefore this enables the enhancement of operationality, space saving, etc., because of the same apparatus specification. Further, since the oxidation and CVD film formation can be effected by the same principle, the oxidation and CVD treatment can also be performed in the same chamber.

(Presumed Mechanism of High-Quality Gate Insulator Formation)

The high-K gate insulator obtained through the above-mentioned steps has an excellent quality. According to the present inventors' knowledge and investigations, the reasons therefor are presumed as follows.

Thus, the oxygen radical produced by the RLSA has a high density, and therefore, the carbon content contained in the film-forming source can be combusted at the same time, during the formation of the high-K insulating film. Further, as compared with the production of radicals by thermal CVD, high-density oxygen radicals can be produced, even at a low temperature (about 300° C.), and therefore, the film can be formed while preventing the device characteristic from the deterioration accompanying the crystallization of the high-K substance due to heat.

(Presumed Mechanism for Preferred MOS Characteristic)

Further, when the gate electrode is formed by a heat treatment under a specific condition in the above-mentioned third step, the resultant MOS-type semiconductor structure has an excellent characteristic. According to the present inventors' knowledge and investigations, the reason therefor may be presumed as follows.

Thus, in the present invention, as described above, an extremely thin high-quality gate insulator can be formed. Based on a combination of the high-quality gate insulator (gate oxide film and/or high-K gate insulator) and the gate electrode (for example, SiGe, amorphous-silicon, poly-silicon by CVD) which has been formed on the high-quality gate insulator, it is possible to realize a good transistor characteristic (such as good interfacial characteristic).

For example, when a cluster-type apparatus as shown in FIG. 2 is used, the exposure of the wafer to the atmosphere can be avoided during a period between the formation of the gate oxide film or high-K gate insulator, and the formation of the gate electrode, to thereby further improve the interfacial characteristic.

Hereinbelow, the present invention will be described in more detail with reference to Examples.

### EXAMPLES

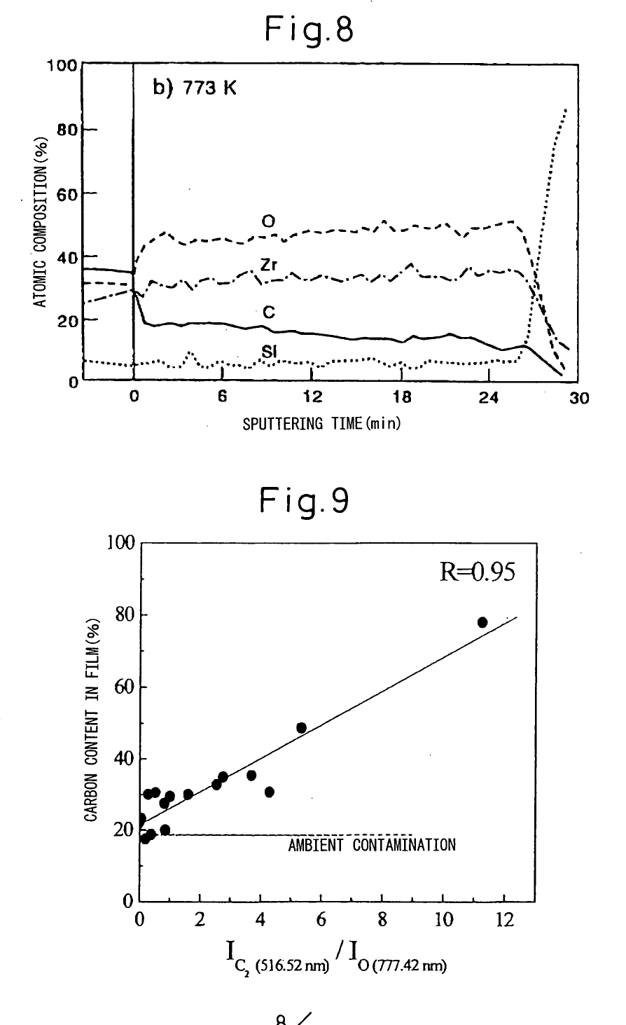

FIG. 8 shows a profile by Auger electron spectroscopy of ZrO₂ produced by the ordinary thermal CVD (M. A. Cameron and S. M. Geage, Thin Solid Films, 348 (1999), 90-98). The abscissa denotes the sputtering time (corresponding to the film thickness in the depth direction) and the ordinate denotes the content. As shown in the figure, it is understood that 10 to 20% of carbon content (C) is contained in the film.

FIG. 9 shows a carbon content in ZrO₂ film which has been produced by using ECR plasma CVD (excerpt from Byeong-Ok Cho, Sandy Lao, Lin Sha and Jane P. Chang, Journal of Vacuum Science and Technology, A 19(6) (November/December 2001), pp. 2751-2761). The abscissa denotes the plasma emission intensity ratio and the ordinate denotes the carbon concentration in the film determined by the XPS analysis. The emission intensity ratio on the abscissa is described below. When plasma is subjected to an emission analysis by OES (optical emission spectroscopy), the light at a wavelength of 516.52 nm indicates the light emission of the carbon content (C₂) and the light at 777.42 nm indicates the light emission of O.

As shown in FIG. 9, it is known that the light emission of C₂ has a proportional relationship with the carbon concentration in the film. The point in FIG. 9 is the XPS analysis result on the ordinate and it is seen that under the process conditions for the provision of a small light emission of C₂, the carbon concentration on the ordinate is maintained at the level equal to that of the reference wafer in the measurement environment. FIGS. 8 and 9 show that the plasma process has a superiority. Further, when the light emission analysis is conducted as shown in FIG. 9, the carbon concentration in the film can be roughly estimated without the analysis of the film. Accordingly, this suggests that the use of plasma may facilitate the optimization of the process.

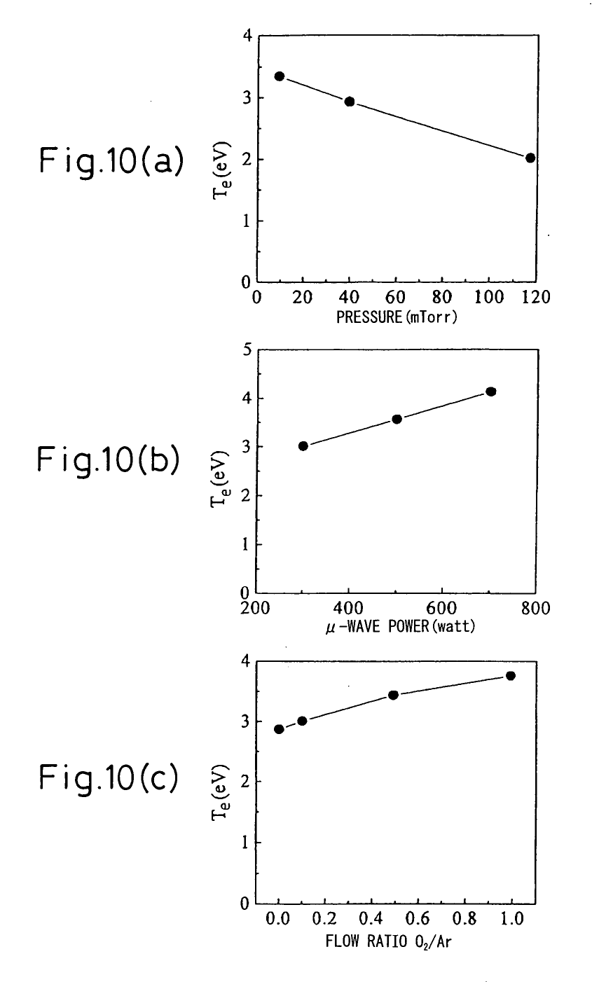

FIG. 10 shows the electron temperature of ECR plasma used in the case of FIG. 9 (excerpt from the above-mentioned publication by Byeong-Ok Cho et al.). As seen from the figure, even when the electron temperature is lowest, the temperature is 2 eV or more. It is reported that the electron density is from 1E11 to 1E12/cm³, but there is a trade-off relationship between the low electron temperature and the high electron density, and a high electron density can be hardly maintained at 2 eV.

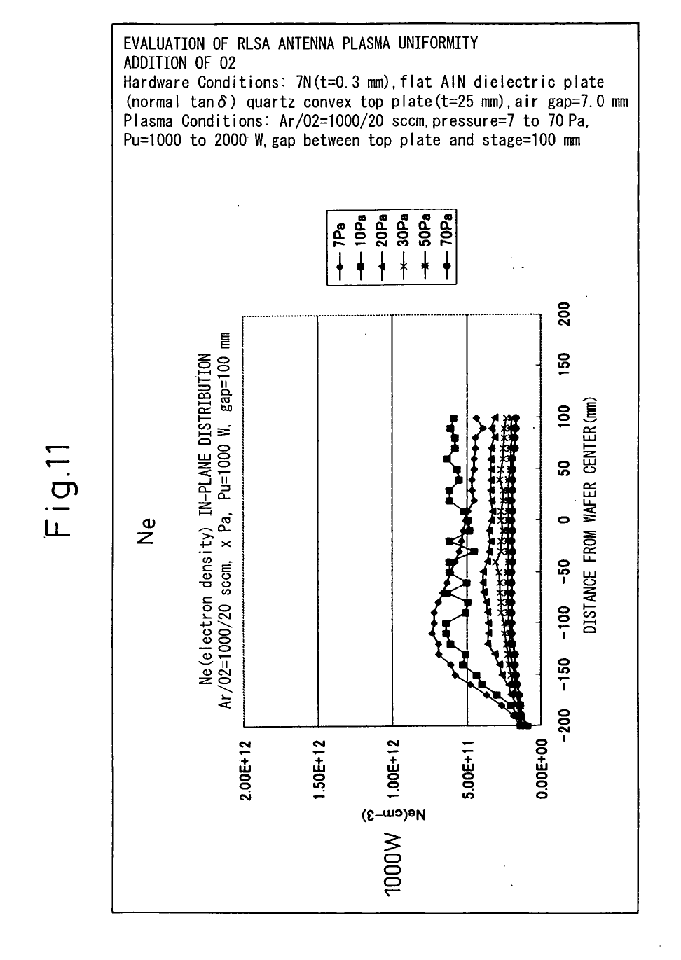

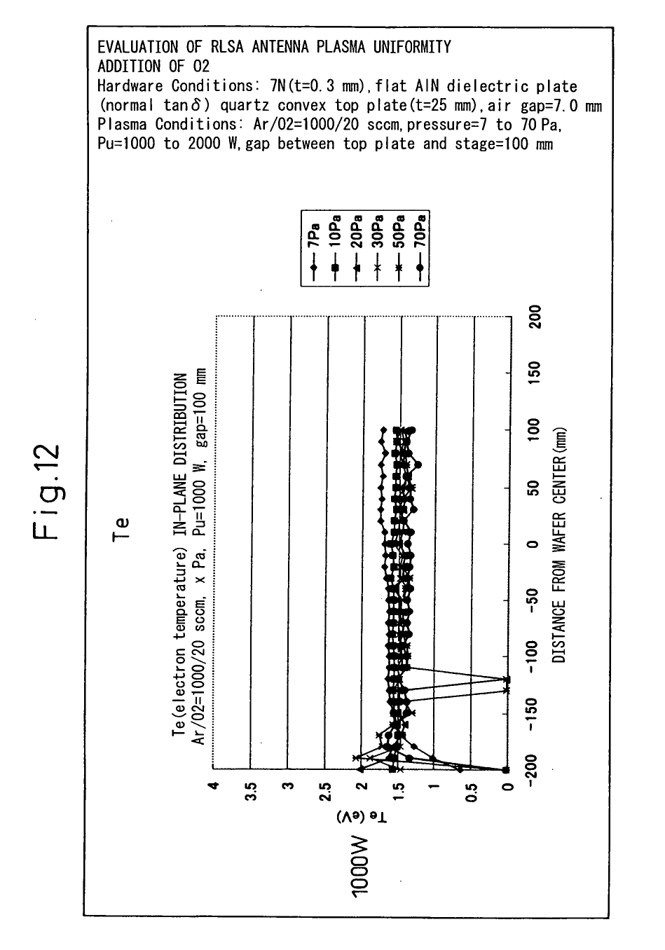

FIGS. 11 and 12 show the results which have been obtained by measuring the electron temperature and density of plasma, when microwave irradiation is effected via a plane antenna member according to the present invention. After the reaction chamber is evacuated (back pressure: 1E-4 Pa or less), 1,000 sccm of Ar gas and 20 sccm of O₂ gas were introduced thereinto and the pressure was maintained at 7 to 70 Pa. From a quartz top plate provided in the upper part of the reaction chamber, microwave was introduced via a plane antenna member so as to generate plasma of Ar and O. A Langmuir probe was inserted into the plasma so as to measure the capacitance component of plasma, whereby the plasma temperature and density were calculated. As seen in the plasma evaluation results of FIGS. 11 and 12, the plasma having an electron density of 1E12 and an electron temperature of 1.5 eV can be formed by this method. Further, the electron density and the electron temperature both are uniform over a range up to a radius of about 150 mm, and this reveals that the method can be applied to a large-diameter wafer (300-mm wafer) by further optimizing the antenna member.

In both of FIGS. 11 and 12, the plasma is measured by using Ar and O₂ gas only, instead of using a process gas. It is expected that, when CH₄ gas, which can provide an atmosphere which is close to that for a process gas, is introduced, the electron temperature may generally be further decreased and plasma capable of providing less damage is formed (see, the above-mentioned publication by Byeong-Ok Cho et al.).

As understood from foregoing description, when a high-dielectric constant material is deposited by using plasma produced by the irradiation of microwave via a plane antenna member as in the present invention, a high-dielectric constant material having a high quality and a reduced carbon concentration can be deposited. Further, the process can be performed at a low temperature up to about 400° C., so that this can also be applied to a substance having a poor heat stability, such as ZrO₂ and HfO₂.

In the foregoing, the present invention is described with respect to a high-dielectric constant material as the film-forming substance, but the plasma CVD method according to the present invention may also be used for the film formation of a substance other than the high-dielectric constant material, such as a film-forming substance for an interlayer insulating film.

### INDUSTRIAL APPLICABILITY

As described hereinabove, the present invention provides a process for producing electronic device material capable of providing an insulating film having a good electrical property.

1. A process for producing an electronic device material comprising forming a film on the surface of an electronic device substrate by using a plasma based on microwave irradiation via a plane antenna member having a plurality of slits, in the presence of a process gas comprising at least a gas containing a film-forming substance and a rare gas.

2. A process for producing an electronic device material according to claim 1, wherein the electronic device substrate is a semiconductor device substrate.

3. A process for producing an electronic device material according to claim 2, wherein the electronic device substrate comprises Si.

4. A process for producing an electronic device material according to claim 3, wherein the film formation provides an insulating film formed on the substrate.

5. A process for producing an electronic device material according to claim 4, wherein the film-forming substance is a film-forming substance for gate insulator of a field-effect transistor.

6. A process for producing an electronic device material according to claim 5, wherein the film forming substance for gate insulator comprises at least one substance selected from the group consisting of: SiO₂, Si₃N₄, Ta₂O₅, ZrO₂, HfO₂, Al₂O₃, La₂O₃, TiO₂, Y₂O₃, BST, Pr₂O₃, Gd₂O₃, CeO₂ and compounds of these substances.

7. A process for producing an electronic device material according to claim 6, wherein the process gas further contains an organic source.

8. A process for producing an electronic device material according to claim 6, wherein the carbon concentration in the insulating film is 15% or less.

9. A process for producing an electronic device material according to claim 4, wherein the film-forming substance is a film-forming substance for an interlayer insulating film.

10. A process for producing an electronic device material according to claim 9, wherein the film-forming substance for the interlayer insulating film contains at least one atom selected from the group consisting of Si, C, O, F, N and H.

11. A process for producing an electronic device material according to claim 4, wherein the plasma has an electron temperature of 2 eV or less and an electron density of 1E11/cm³ or more.

12. A process for producing an electronic device material according to claim 4, wherein the electronic device is a semiconductor device.
